(19) United States
(12) Patent Application Publication
(10) Pub. No.: US 2024/0054274 A1
(43) Pub. Date: Feb. 15, 2024

(54) DUMMY METAL FILLING METHOD AND APPARATUS, DEVICE AND MEDIUM

(71) Applicant: CHANGXIN MEMORY TECHNOLOGIES, INC., Hefei (CN)

(72) Inventor: Kun WENG, Hefei (CN)

(21) Appl. No.: 18/155,768

(22) Filed: Jan. 18, 2023

(30) Foreign Application Priority Data
Aug. 9, 2022 (CN) 202210952859.7

(51) Int. Cl. G06F 30/3953; G06F 30/398

(52) U.S. Cl. CPC G06F 30/3953; G06F 30/398

(57) ABSTRACT

Embodiments provide a dummy metal filling method and apparatus, a device and a medium, and relates to the field of semiconductor fabrication technologies. The method includes: providing an initial layout including a potential line; determining same-layer and same-net metal wires of each metal pattern layer based on a wiring connection relationship in the initial layout; determining a to-be-filled region in the each metal pattern layer based on the same-layer and same-net metal wires; filling same-layer metal wires into the to-be-filled region in the each metal pattern layer, and adding a connection hole, such that the same-layer metal wires are connected to the same potential line; and adding dummy metal on a layout where the filling the same-layer metal wires is completed, to output a target layout.

### CROSS-REFERENCE TO RELATED APPLICATION

This application claims priority to Chinese Patent Application No. 202210952859.7, titled “DUMMY METAL FILLING METHOD AND APPARATUS, DEVICE AND MEDIUM” and filed to the State Patent Intellectual Property Office on Aug. 9, 2022, the entire contents of which are incorporated herein by reference.

### TECHNICAL FIELD

The present disclosure relates to the field of semiconductor technology, and more particularly, to a dummy metal filling method, a dummy metal filling apparatus, an electronic device, and computer-readable storage medium.

### BACKGROUND

In integrated circuit processes, due to different wafer densities, a pattern effect occurs, i.e., a micro-loading effect. The micro-loading effect is a phenomenon that occurs when both a high-density pattern and a low-density pattern are exposed, etched, and/or polished. Due to a difference between exposure/etching/polishing rates at different positions on a film, response amplitude generated by exposure/etching/polishing becomes locally dense or sparse, thereby causing nonuniformity in the etching/polishing rates or pattern dimensions after exposure.

In related technologies, a layout design in which dummy metal is filled is generally used, and the dummy metal is filled to a position with a low pattern density. However, the dummy metal generates additional parasitic capacitance. Consequently, a processing speed of a chip is decreased.

It should be noted that information disclosed in the above background section is used merely for enhancement of understanding of the background of the present disclosure, and therefore may include information that does not constitute the prior art known to those of ordinary skill in the art.

### SUMMARY

The present disclosure provides a dummy metal filling method and apparatus, a device and a chip.

According to one aspect of the present disclosure, there is provided a dummy metal filling method, which includes: providing an initial layout, where the initial layout includes a potential line; determining same-layer and same-net metal wires of each metal pattern layer based on a wiring connection relationship in the initial layout, where the same-layer and same-net metal wires are wirings positioned on a same metal pattern layer and connected to a same potential line; determining a to-be-filled region in the each metal pattern layer based on the same-layer and same-net metal wires; filling same-layer metal wires into the to-be-filled region in the each metal pattern layer, and adding a connection hole, such that the same-layer metal wires are connected to the same potential line; and adding dummy metal on a layout where the filling the same-layer metal wires is completed, to output a target layout.

In another aspect of the present disclosure, there is provided a dummy metal filling apparatus, which includes: an initial layout providing module configured to provide an initial layout, where the initial layout comprises a potential line; a same-layer and same-net determination module configured to determine same-layer and same-net metal wires of each metal pattern layer based on a wiring connection relationship in the initial layout, where the same-layer and same-net metal wires are wirings positioned on a same metal pattern layer and connected to a same potential line; a filling region determination module configured to determine a to-be-filled region in the each metal pattern layer based on the same-layer and same-net metal wires; a same-layer metal filling module configured to fill same-layer metal wires into the to-be-filled region in the each metal pattern layer, and add a connection hole, such that the same-layer metal wires are connected to the same potential line; and a target layout output module configured to add dummy metal on a layout where the filling the same-layer metal wires is completed, to output a target layout.

According to yet another aspect of the present disclosure, there is provided an electronic device, which includes: a processor; and a memory configured to store executable instructions of the processor. The processor is configured to execute the executable instructions to implement the dummy metal filling method.

According to still another aspect of the present disclosure, there is provided a computer-readable storage medium storing a computer program thereon. The computer program is executable by the processor, whereby the dummy metal filling method is implemented.

It is to be understood that the above general description and the detailed description below are merely exemplary and explanatory, and do not limit the present disclosure.

### BRIEF DESCRIPTION OF THE DRAWINGS

The accompanying drawings herein are incorporated in and constitute a part of this specification, illustrate embodiments conforming to the present disclosure and, together with the specification, serve to explain the principles of the present disclosure. Apparently, the accompanying drawings in the following description show merely some embodiments of the present disclosure, and persons of ordinary skill in the art may still derive other drawings from these accompanying drawings without creative efforts.

FIG. 1 illustrates a principle diagram of filling dummy metal in related technologies;

FIG. 2 illustrates a flowchart of a dummy metal filling method according to an embodiment of the present disclosure;

FIG. 3a illustrates a schematic structural diagram of an initial layout according to an embodiment of the present disclosure;

FIG. 3b illustrates a schematic structural diagram of a layout after a same-layer metal wire is filled into a to-be-filled region according to an embodiment of the present disclosure;

FIG. 4 illustrates a flowchart of another dummy metal filling method according to an embodiment of the present disclosure;

FIG. 5 illustrates a flowchart of still another dummy metal filling method according to an embodiment of the present disclosure;

FIG. 6 illustrates a schematic diagram of a repeated filling manner according to an embodiment of the present disclosure;

FIG. 7 illustrates a schematic diagram of a staggered filling manner according to an embodiment of the present disclosure;

FIG. 8 illustrates a flowchart of still another dummy metal filling method according to an embodiment of the present disclosure;

FIG. 9 illustrates a schematic diagram of a dummy metal filling apparatus according to an embodiment of the present disclosure;

FIG. 10 illustrates a schematic structural diagram of an electronic device according to an embodiment of the present disclosure; and

FIG. 11 illustrates a schematic diagram of a computer program product according to an embodiment of the present disclosure.

Reference numerals: 101: first-layer potential line; 102: second-layer potential line; 103: first-layer to-be-filled region; 104: second-layer to-be-filled region; 201: potential line; 2011: first potential line; 2012: second potential line; 202: same-layer and same-net metal wire; 203: to-be-filled region; 204: same-layer metal wire; 2041: first same-layer metal wire; and 2042: second same-layer metal wire.

### DETAILED DESCRIPTION

Embodiments of the present disclosure will be described in more detail below with reference to the accompanying drawings. Although the accompanying drawings display some embodiments of the present disclosure, it should be understood that the present disclosure may be implemented in various forms but not limited by the embodiments set forth herein. Rather, these embodiments are provided such that the present disclosure will be more thorough and complete, and can fully convey the scope of the present disclosure to those skilled in the art.

Terms “first” and “second” are used only for purposes of description and are not interpreted as indicating or implying relative importance or implying the number of indicated technical features. Thus, the feature defined with “first” and “second” may explicitly or implicitly include at least one such feature. In the description of the present disclosure, “a plurality of” refers to at least two, unless otherwise expressly specified.

In the description of the present disclosure, it is to be noted that unless specified or limited otherwise, terms “installation”, “connecting” or “connection” should be understood in a broad sense, which may be, for example, a fixed connection, a detachable connection or integrated connection, a mechanical connection or an electrical connection or mutual communication, a direct connection or indirect connection by means of an intermediary, or internal communication between two components or an interaction relationship between two components. For those of ordinary skill in the art, concrete meanings of the above terms in the present disclosure may be understood based on concrete circumstances.

The following disclosure provides many different embodiments or examples to implement different structures of the present disclosure. To simplify the disclosure of the present disclosure, components and settings in particular examples are described hereinafter. Certainly, these examples are merely for illustrative purposes, and are not intended to limit the present disclosure. In addition, in the present disclosure, reference numerals and/or reference letters may be repeated in different examples. This repetition is for the purpose of simplicity and clarity, and does not in itself indicate a relationship between the various embodiments and/or settings that are discussed.

Layouts are patterns that include relevant physical information, such as a device type, a device dimension, relative positions between devices, and a connection relationship between the devices in an integrated circuit. These patterns comprise patterns positioned on different layers. The devices may include various semiconductor elements, such as a transistor, a capacitor, and a resistor.

A layout design of the integrated circuit is to map a circuit design drawing or a circuit description language to a physical description level, such that a designed circuit can be mapped to wafer production.

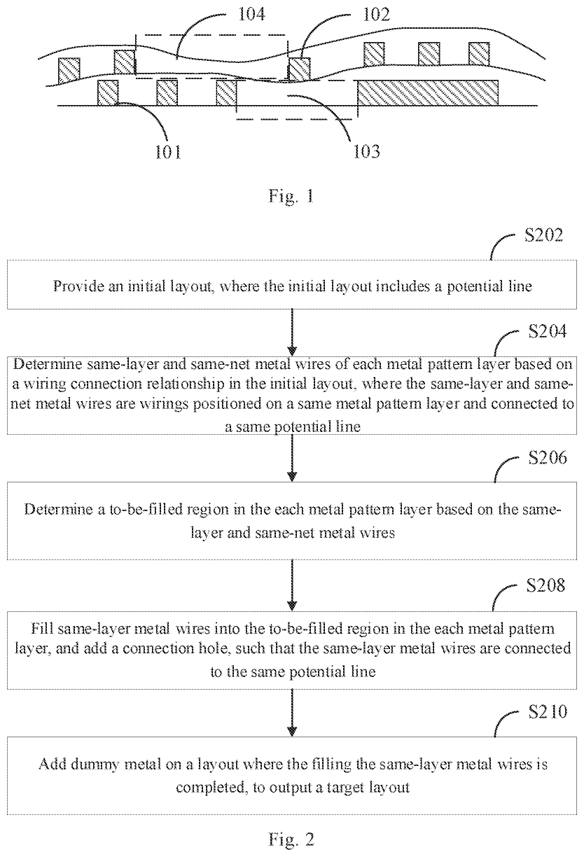

FIG. 1 illustrates a principle diagram of filling dummy metal in related technologies. As shown in FIG. 1, a layout includes at least one metal pattern layer, for example, two metal pattern layers in FIG. 1. The two metal pattern layers are respectively a first metal pattern layer positioned on a lower layer and a second metal pattern layer positioned on an upper layer, a plurality of first-layer potential lines 101 are arranged on the first metal pattern layer, and a plurality of second-layer potential lines 102 are arranged on the second metal pattern layer. First-layer to-be-filled regions 103 at a larger interval exist among the first-layer potential lines 101, and second-layer to-be-filled regions 104 at a larger interval exist among the second-layer potential lines 102. As can be found from FIG. 1, flatness of a surface of an initial layout is poorer due to different pattern densities and/or positions of the metal pattern layers.

In the related technologies, dummy metal is generally filled in the first-layer to-be-filled region 103 and the second-layer to-be-filled region 104, to improve the pattern density, thereby avoiding a pattern effect. However, the dummy metal also brings a negative effect. For example, filling the dummy metal generates additional parasitic capacitance. Consequently, a processing speed of a chip is decreased.

Therefore, to minimize, as much as possible, the additional parasitic capacitance generated by the dummy metal, in addition to optimizing a manner of filling the dummy metal, whether another method may be designed to replace the dummy metal further needs to be studied while a process requirement can be met.

On this basis, the present disclosure provides a dummy metal filling method. In a spare region of a layout, a to-be-filled region of same-layer metal wires is determined according to a wiring mode of a potential line, and a corresponding same-layer metal wire is automatically added in the to-be-filled region, thereby increasing a width of the entire potential line, enhancing strength of the potential line, and reducing an area of the dummy metal needs to be filled. In this way, the extra parasitic capacitance generated by filling the dummy metal is greatly reduced, and the processing speed of the chip is improved.

It should be pointed out that the embodiments of the present disclosure and the technical features in the embodiments may be combined with each other without conflict.

This exemplary embodiment is described in detail below with reference to the accompanying drawings and the embodiments.

FIG. 2 illustrates a flowchart of a dummy metal filling method according to an embodiment of the present disclosure. As shown in FIG. 2, the dummy metal filling method in this embodiment includes following steps.

Step S202: providing an initial layout, where the initial layout includes a potential line.

The initial layout in this embodiment includes at least a potential line and a wiring connection relationship in the initial layout, and the wiring connection relationship may include a connection relationship between a metal wire in each metal pattern layer in the initial layout and the potential line. It should be noted that, during layout design, different devices, metal wires, and the like may be arranged on different layers, to perform operation only for a certain layer. By distinguishing between different pattern layers, it is convenient to screen the metal pattern layers and improve design efficiency.

It should be noted that the potential line may include at least one of a power wire and a ground wire with different voltage values. For example, the voltage values provided by the power wire may include 5 V, 12 V, 24 V, and the like.

For example, in an integrated circuit, N-type metal-oxide-semiconductors (NMOS) of different types are generally used. A gate voltage of one NMOS generally is 5 V, a drain voltage of the NMOS is generally 12 V, and a source of the NMOS is grounded by means of a load resistor. In this case, the NMOS cannot work normally unless voltage values of 0 V, 5 V and 12 V are employed.

For other structures such as a device and a chip, a voltage value of a potential line needs to be determined depending on an actual situation, and is not limited in the present disclosure.

Step S204: determining same-layer and same-net metal wires of each metal pattern layer based on a wiring connection relationship in the initial layout, where the same-layer and same-net metal wires are wirings positioned on a same metal pattern layer and connected to a same potential line.

In this embodiment, the same-layer and same-net metal wires belong to the same metal pattern layer and are connected to the same potential line. After the layout connection relationship is determined, the same-layer and same-net metal wires may be screened in different ways.

For example, after the layout connection relationship is determined, metal wires connected to the same potential line are first screened, and then metal wires positioned on the same metal pattern layer are screened from the metal wires connected to the same potential line.

For example, after the layout connection relationship is determined, metal wires positioned on the same metal pattern layer are first screened, and then metal wires connected to the same potential line are screened from the metal wires positioned on the same metal pattern layer.

Step S206: determining a to-be-filled region in the each metal pattern layer based on the same-layer and same-net metal wires.

The to-be-filled region in this embodiment is a spare region into which the same-layer metal wire in each metal pattern layer is filled. The to-be-filled region may be of a rectangle, a square, or other irregular figures, and a shape of the same-layer metal wire may be a straight line, a broken line, or the like. This is not limited in the present disclosure.

Generally, a dimension of the to-be-filled region (for example, a width of the to-be-filled region) is at least greater than that of the same-layer metal wire.

In one embodiment, the to-be-filled region in each metal pattern layer is determined in the following manner.

When an interval between two adjacent same-layer and same-net metal wires satisfies a preset condition, a region between the two adjacent same-layer and same-net metal wires is determined as the to-be-filled region.

The preset condition includes the interval between the two adjacent same-layer and same-net metal wires being greater than or equal to a preset interval threshold. It should be noted that the preset interval threshold may be a fixed value or may be a certain interval value range, and a value of the preset interval threshold can be determined based on the width of the same-layer metal wire and an interval between the same-layer metal wire and the same-layer and same-net metal wire. This is not limited in the present disclosure.

Step S208: filling same-layer metal wires into the to-be-filled region in the each metal pattern layer, and adding a connection hole, such that the same-layer metal wires are connected to the same potential line.

It should be noted that after the same-layer metal wire is filled in the to-be-filled region, a connection hole needs to be added, such that the same-layer metal wire is electrically connected to a corresponding potential line, thereby achieving a purpose of increasing a width and strength of the potential line.

Step S210: adding dummy metal on a layout where the filling the same-layer metal wires is completed, to output a target layout.

After the same-layer metal wire is filled in the to-be-filled region of each metal pattern layer in the initial layout, there may still be a spare region on the layout. The pattern density is improved by adding the dummy metal, to improve the flatness of the surface of the layout.

The present disclosure provides a dummy metal filling method. In a spare region of a layout, a to-be-filled region of same-layer metal wires is determined according to a wiring mode of a potential line, and a corresponding same-layer metal wire is automatically added in the to-be-filled region, thereby increasing a width of the entire potential line, enhancing strength of the potential line, and reducing an area of the dummy metal needs to be filled.

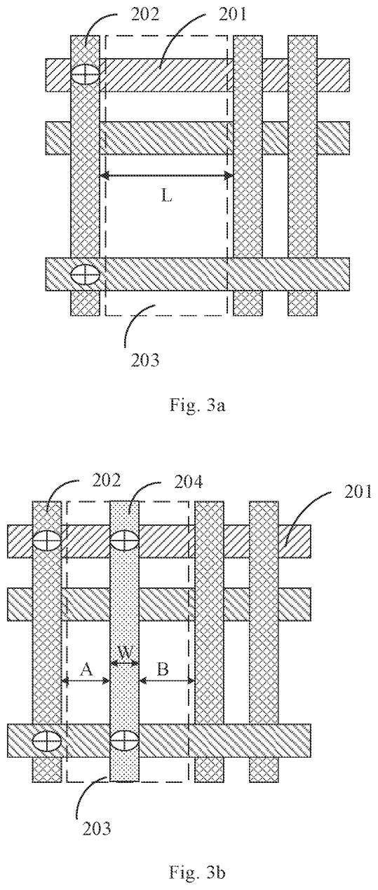

To understand a dummy metal filling method in the present disclosure, the following description is made with reference to FIG. 3a and FIG. 3b.

FIG. 3a is a schematic structural diagram of an initial layout according to an embodiment of the present disclosure. As shown in FIG. 3a, the initial layout includes three potential lines 201 horizontally arranged and three same-layer and same-net metal wires 202 perpendicular to the potential lines 201. One end of a first same-layer and same-net metal wire is connected, through a connection hole, to a potential line of a metal pattern layer positioned on a lower layer, and the other end of the first same-layer and same-net metal wire is connected, through the connection hole, to a potential line of a metal pattern layer positioned on an upper layer. As can be found from FIG. 3a, an interval L between the first same-layer and same-net metal wire and a second same-layer and same-net metal wire is wide, and the foregoing interval region is determined as a to-be-filled region 203 of the metal pattern layer.

FIG. 3b is a schematic structural diagram of the layout after the same-layer metal wire is filled into the to-be-filled region according to an embodiment of the present disclosure. As shown in FIG. 3b, a same-layer metal wire 204 is filled into the to-be-filled region 203. A width W of the same-layer metal wire 204, an interval A between the same-layer metal wire 204 and the first same-layer and same-net metal wire, an interval B between the same-layer metal wire 204 and the second same-layer and same-net metal wire meet the following relationship: L=W+A+B

It should be noted that the width W of the same-layer metal wire 204 may be the same as or different from a width of the same-layer and same-net metal wire 202. The interval A between the same-layer metal wire 204 and the first same-layer and same-net metal wire may be the same as or different from the interval B between the same-layer metal wire 204 and the second same-layer and same-net metal wire. Value ranges of W, A and B are preset in an auto-fill program.

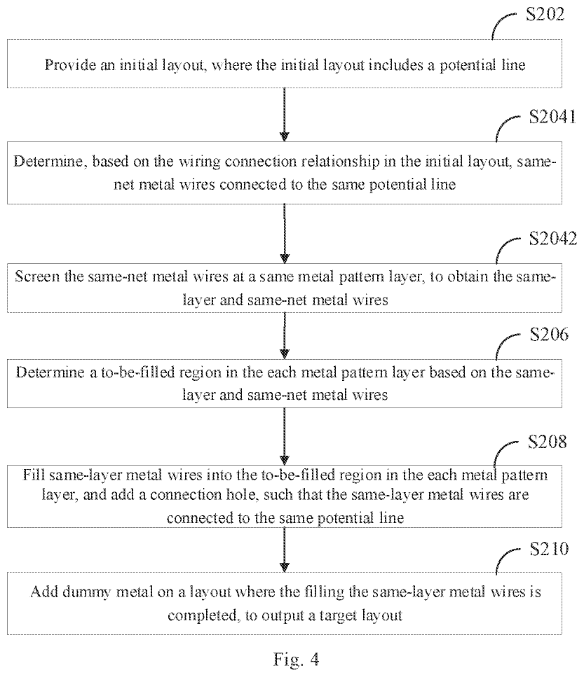

FIG. 4 illustrates a flowchart of another dummy metal filling method according to an embodiment of the present disclosure. On the basis of FIG. 2, Step S204 is further refined into S2041˜S2042. As shown in FIG. 4, the dummy metal filling method of this embodiment includes Steps S202, S2041˜S2042, and S206˜S210, including:

Step S2041: determining, based on the wiring connection relationship in the initial layout, same-net metal wires connected to the same potential line; and Step S2042: screening the same-net metal wires at a same metal pattern layer, to obtain the same-layer and same-net metal wires.

It should be noted that, Steps S202 and S206-210 are implemented in the same manner as in the foregoing embodiment, and thus detailed descriptions thereof are omitted here.

It is worth noting that, for the manner of determining the same-layer and same-net metal wires, sequences of the above Steps S2041 and S2042 may be adjusted, which is not limited in the present disclosure.

In the present disclosure, number of the to-be-filled regions in each metal pattern layer can be determined by screening the same-layer and same-net metal wires, and during filling, the to-be-filled regions can be filled one by one, to improve accuracy of filling the same-layer metal wires.

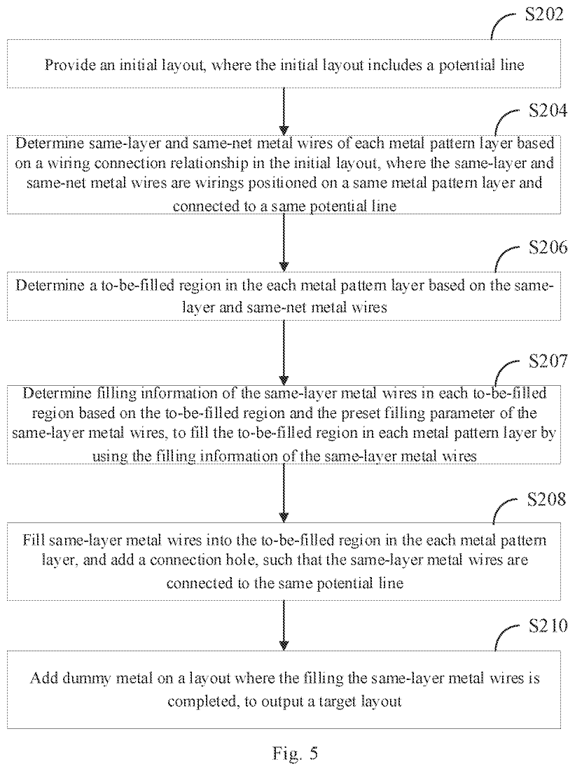

FIG. 5 illustrates a flowchart of still another dummy metal filling method according to an embodiment of the present disclosure. On the basis of the embodiment of FIG. 2, before Step S208, Step S207 is added, such that information of the same-layer metal wire needing to be filled is determined based on the to-be-filled region and a preset filling parameter of the same-layer metal wires. As shown in FIG. 5, in one embodiment, the dummy metal filling method includes Steps S202-S210, including:

Step S207: determining filling information of the same-layer metal wires in each to-be-filled region based on the to-be-filled region and the preset filling parameter of the same-layer metal wires, to fill the to-be-filled region in each metal pattern layer by using the filling information of the same-layer metal wires.

It should be noted that, Steps S202˜S206 and S208˜S210 are implemented in the same manner as in the foregoing embodiment, and thus detailed descriptions thereof are omitted here.

In this embodiment, the filling parameter of the same-layer metal wire is preset in the auto-fill program, such that filling information of the same-layer metal wire can be obtained by directly invoking the auto-fill program, to automatically fill the metal wire.

In one embodiment, the filling parameter of the same-layer metal wires includes at least one of a width of the same-layer metal wire, an interval between the same-layer metal wire and the same-layer and same-net metal wire, and an interval between adjacent same-layer metal wires. It should be noted that the filling parameter of the same-layer metal wire may be a value or a value range. The value of the filling parameter is determined according to a process parameter, and is not limited in the present disclosure.

Filling information of same-layer metal wires in each to-be-filled region includes at least one of a filling number, filling positions, filling shapes and an actual filling interval of the same-layer metal wires. It should be noted that the filling information of the same-layer metal wires in the to-be-filled regions in different metal pattern layers may be the same or may be different; and the filling information of the same-layer metal wires in different to-be-filled regions in the same metal pattern layer may be the same or may be different. The actual filling interval of the same-layer metal wires may be adjusted based on the filling parameter, and is not limited in the present disclosure.

In the present disclosure, the filling information of the same-layer metal wire is conveniently and quickly determined based on the to-be-filled region in each metal pattern layer and the preset filling parameter of the same-layer metal wire, such that a metal wire is automatically filled into the to-be-filled region in each metal pattern layer based on the filling information of the same-layer metal wire, thereby increasing the filling efficiency of the metal wire.

In one embodiment, the filling the same-layer metal wires into the to-be-filled region in the each metal pattern layer includes:
filling the same-layer metal wires into the to-be-filled region in the each metal pattern layer in a repeated filling manner and/or a staggered filling manner, where the same-layer metal wires using the repeated filling manner are connected to the same potential line, and the same-layer metal wires using the staggered filling manner are alternately connected to different potential lines.

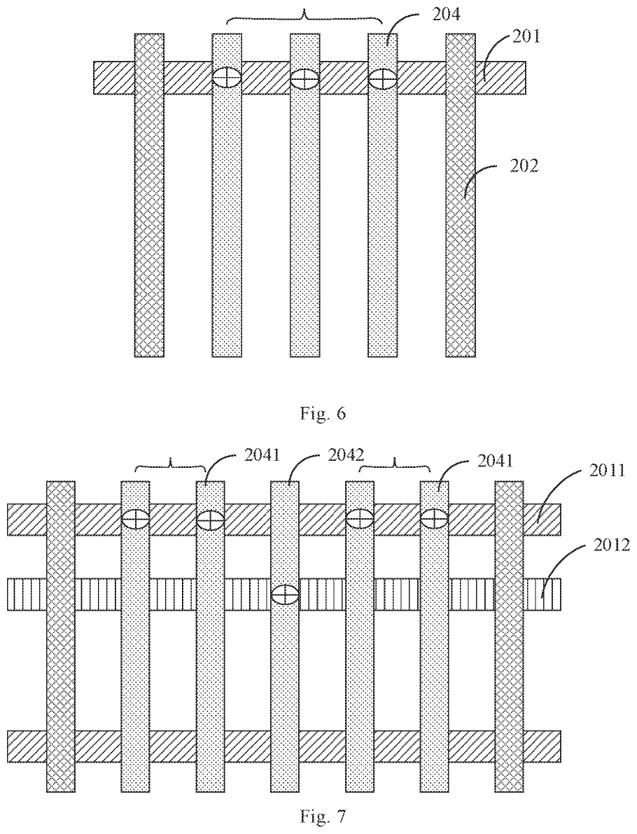

FIG. 6 illustrates a schematic diagram of a repeated filling manner according to an embodiment of the present disclosure. As shown in FIG. 6, the initial layout includes the potential line 201 and the same-layer and same-net metal wire 202. An interval between two adjacent same-layer and same-net metal wires 202 is used as a to-be-filled region. At least one same-layer metal wire 204 is filled into the to-be-filled region, and one end of the at least one same-layer metal wire 204 is provided with a connection hole, such that the at least one same-layer metal wire 204 is connected to the same potential line 201.

FIG. 7 illustrates a schematic diagram of a staggered filling manner according to an embodiment of the present disclosure. As shown in FIG. 7, the initial layout includes a first potential line 2011, a second potential line 2012, and at least two same-layer and same-net metal wires. An interval between the two same-layer and same-net metal wires forms a to-be-filled region, and at least two same-layer metal wires 204 are filled into the to-be-filled region. The same-layer metal wires 204 include at least a first same-layer metal wire 2041 and a second same-layer metal wire 2042, the first same-layer metal wire and the second same-layer metal wire 2042 are staggered, the first same-layer metal wire 2041 is connected to the first potential line 2011 through a connection hole, and the second same-layer metal wire 2042 is connected to the second potential line 2012 through a connection hole, to implement staggered filling. It should be noted that the first same-layer metal wire 2041 or the second same-layer metal wire 2042 includes at least one metal wire.

In addition, the same-layer metal wires may be further grouped into two groups, the two groups of the same-layer metal wires are arranged in the to-be-filled region in turn, and the two groups of the same-layer metal wires are electrically connected to different potential lines respectively through connection holes.

It should be noted that forms of the foregoing filling manners are only examples provided to describe the embodiments of the present disclosure, and should not be considered as limitations on the protection scope of the present disclosure.

In the present disclosure, the same-layer metal wires is automatically filled in a repeated filling manner or a staggered filling manner, thereby fully considering use, a function, and another factor of the same-layer metal wire, greatly improving the strength and the performance of the potential line, and improving a processing speed of a chip.

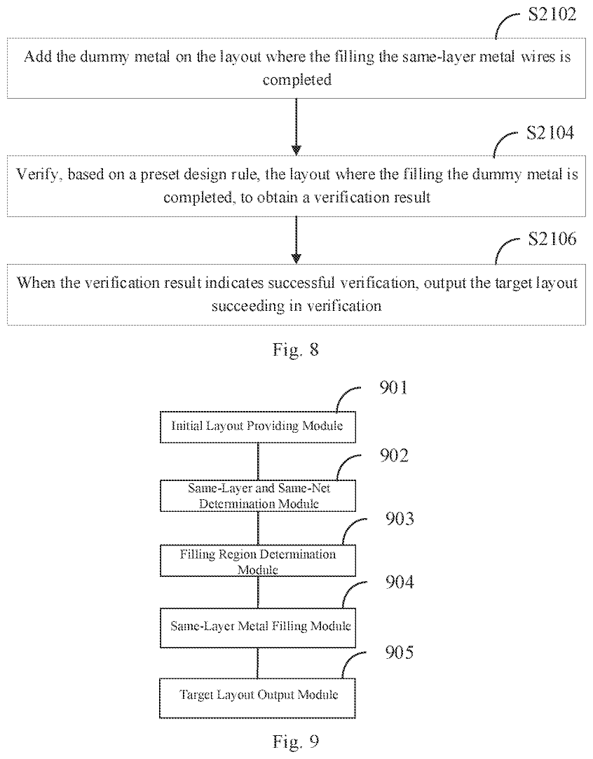

FIG. 8 illustrates a flowchart of still another dummy metal filling method according to an embodiment of the present disclosure. As shown in FIG. 8, in one embodiment, the Step S210 of adding the dummy metal on the layout where the filling the same-layer metal wires is completed, to output a target layout includes: S2102: adding the dummy metal on the layout where the filling the same-layer metal wires is completed; S2104: verifying, based on a preset design rule, the layout where the filling the dummy metal is completed, to obtain a verification result; and S2106: when the verification result indicates successful verification, outputting the target layout succeeding in verification.

A preset design rule in this embodiment includes at least one of a design rule check (DRC), an electrical rule check (ERC), a layout versus schematic (LVS) consistency check, a circuit netlist extraction (NET) of a layout and a layout parameter extraction (LPE).

Description is provided below by taking the DRC as an example.

The DRC aims at checking whether various dimensions of patterns in each mask layer in the layout meet requirements of a design rule. The design rule of the layout is determined based on a dimension of a minimum pattern that can be produced by means of a production line of a process, a width of a thinnest line, and a pitch between lines.

When the DRC is performed on the layout, the check is mainly performed in two aspects. In one aspect, only a minimum dimension and a minimum width need to be checked for the widths and the pitch between geometric patterns on the same layer. In the other aspect, for the pitch between patterns on different layers and an overlay pitch, it is necessary to check whether patterns on two different layers are completely nested, intersected, tangent, and completely separated, etc.

In some embodiments, it is checked whether the layout obtained after the same-layer metal wire and the dummy metal are inserted meets the DRC.

When the layout obtained after the same-layer metal wire and the dummy metal are inserted does not meet the DRC, this indicates that surface verification fails, and it is returned to the step of filling the same-layer metal wire or the dummy metal for modification. When the layout meets the DRC, this indicates the verification is successful, and the same-layer metal wire and the dummy metal inserted meet the design requirement, and the target layout can be obtained.

It should be noted that a preset design rule (for example, the design rule check) is preset in a program of automatically filling a metal wire, to automatically filling the metal wire. In addition, the filled same-layer metal wire meets a process requirement, thereby avoiding DRC violation, and improving the circuit design reliability.

Based on the same inventive concept, an embodiment of the present disclosure also provides a dummy metal filling apparatus, as described in the following embodiments. Because the principle of solving the problem in this apparatus embodiment is similar to that in the foregoing method embodiment, reference may be made to the implementation of the foregoing method embodiment for implementation of this apparatus embodiment, and thus repeated details are omitted.

FIG. 9 illustrates a schematic diagram of a dummy metal filling apparatus according to an embodiment of the present disclosure. As shown in FIG. 9, the dummy metal filling apparatus of this embodiment includes: an initial layout providing module 901 configured to provide an initial layout, where the initial layout comprises a potential line; a same-layer and same-net determination module 902 configured to determine same-layer and same-net metal wires of each metal pattern layer based on a wiring connection relationship in the initial layout, where the same-layer and same-net metal wires are wirings positioned on a same metal pattern layer and connected to a same potential line; a filling region determination module 903 configured to determine a to-be-filled region in the each metal pattern layer based on the same-layer and same-net metal wires; a same-layer metal filling module 904 configured to fill same-layer metal wires into the to-be-filled region in the each metal pattern layer, and add a connection hole, such that the same-layer metal wires are connected to the same potential line; and a target layout output module 905 configured to add dummy metal on a layout where the filling the same-layer metal wires is completed, to output a target layout.

In one embodiment of the present disclosure, the same-layer and same-net determination module 902 includes a same-network metal screening submodule and a same-layer metal screening submodule not shown in the drawings.

The same-net metal screening submodule is configured to determine same-net metal wires connected to the same potential line according to a wiring connection relationship in the initial layout.

The same-layer metal screening submodule is configured to screen the same-net metal wires at the same metal pattern layer, to obtain the same-layer and same-net metal wires.

In one embodiment of the present disclosure, the apparatus further includes a filling information determination module not shown in the drawings. The filling information determination module is configured to fill same-layer metal wires into the to-be-filled region in the each metal pattern layer, and add a connection hole, such that the same-layer metal wires are connected to the same potential line, and determine filling information of the same-layer metal wires in each to-be-filled region based on the to-be-filled region and a preset filling parameter of the same-layer metal wires.

The same-layer metal filling module 904 is configured to fill the to-be-filled region in the each metal pattern layer by using the filling information of the same-layer metal wires.

It should be noted that the filling parameter of the same-layer metal wire includes at least one of a width of the same-layer metal wire, an interval between the same-layer metal wire and the same-layer and same-net metal wire, and an interval between adjacent same-layer metal wires.

It should be noted that the filling information of the same-layer metal wires in each to-be-filled region includes at least one of a filling number, filling positions, and an actual filling interval of the same-layer metal wires.

In one embodiment of the present disclosure, the same-layer metal filling module 904 is configured to fill the same-layer metal wires into the to-be-filled region in the each metal pattern layer in a repeated filling manner and/or a staggered filling manner, where the same-layer metal wires using the repeated filling manner are connected to the same potential line, and the same-layer metal wires using the staggered filling manner are alternately connected to different potential lines.

In one embodiment of the present disclosure, the potential line includes at least one of a power wire and a ground wire with different voltage values.

In one embodiment of the present disclosure, the target layout output module 905 includes a dummy metal filling submodule, a layout verification submodule and a layout output submodule not shown in the drawings.

The dummy metal filling submodule is configured to add the dummy metal on the layout where the filling the same-layer metal wires is completed.

The layout verification submodule is configured to verify, based on the preset design rule, the layout where the filling the dummy metal is completed, to obtain a verification result.

The layout output submodule is configured to output, when the verification result indicates successful verification, the target layout succeeding in verification.

In one embodiment of the present disclosure, the filling region determination module 903 is configured to determine, when an interval between two adjacent same-layer and same-net metal wires meets a preset condition, a region between the two adjacent same-layer and same-net metal wires as the to-be-filled region.

It should be noted that the preset condition includes the interval between the two adjacent same-layer and same-net metal wires being greater than or equal to the preset interval threshold.

The present disclosure provides a dummy metal filling apparatus. In a spare region of a layout, a to-be-filled region of same-layer metal wires is determined according to a wiring mode of a potential line, and a corresponding same-layer metal wire is automatically added in the to-be-filled region, thereby increasing a width of the entire potential line, enhancing strength of the potential line, and reducing an area of the dummy metal needs to be filled.

As can be appreciated by one skilled in the art, aspects of the present disclosure may be embodied as a system, method or program product. Accordingly, aspects of the present disclosure may take the form of an entirely hardware embodiment, an entirely software embodiment (including firmware, micro-code, etc.) or an embodiment combining software and hardware aspects that may all generally be referred to herein as a “circuit,” “module” or “system.”

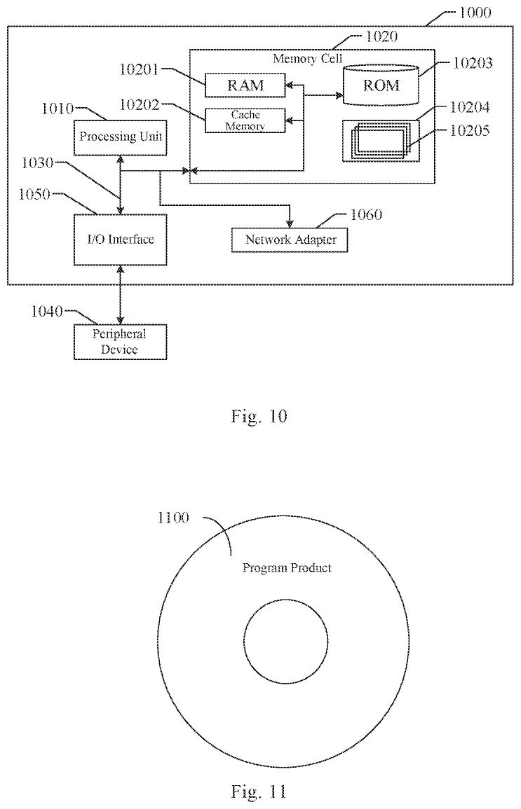

An electronic device 1000 according to this embodiment of the present disclosure is described below with reference to FIG. 10. The electronic device 1000 as shown in FIG. 10 is merely an example, and no limitation should be imposed on functions or scope of use of the embodiment of the present disclosure.

As shown in FIG. 10, the electronic device 1000 is shown in the form of a general-purpose computing device. Components of the electronic device 1000 may include, but are not limited to: at least one processing unit 1010, at least one memory cell 1020, and a bus 1030 connecting different system components (including the memory cell 1020 and the processing unit 1010).

The memory cell stores a program code, which may be executed by the processing unit 1010, such that the processing unit 1010 performs steps described in the “exemplary method” portions of the specification according to exemplary embodiments of the present disclosure. For example, the processing unit 1010 may perform following steps of: providing an initial layout as shown in FIG. 2, where the initial layout includes a potential line; determining same-layer and same-net metal wires of each metal pattern layer based on a wiring connection relationship in the initial layout, where the same-layer and same-net metal wires are wirings positioned on the same metal pattern layer and connected to the same potential line; determining the to-be-filled region in the each metal pattern layer based on the same-layer and same-net metal wires; filling the same-layer metal wires into the to-be-filled region in the each metal pattern layer, and adding a connection hole, such that the same-layer metal wires are connected to the same potential line; and adding dummy metal on the layout where the filling the same-layer metal wires is completed, to output the target layout.

The memory cell 1020 may include readable media in the form of volatile memory cell, such as a random access memory (RAM) 10201 and/or a cache memory 10202. Furthermore, the memory cell 720 may further include a read-only memory (ROM) 10203.

The memory cell 1020 may include a program/utility tool 10204 having a group of (at least one) program modules 10205. The program modules 10205 include, but are not limited to: an operating system, one or more applications, other program modules and program data. Each or a certain combination of these examples may include implementation of network environment.

The bus 1030 may represent one or more of a plurality of bus structures, including a memory bus or memory controller, a peripheral bus, an accelerated graphics port, a processing unit or a local bus using any bus structure among the plurality of bus structures.

The electronic device 1000 may communicate with one or more peripheral devices 1040 (such as keyboards, pointing devices, Bluetooth devices, etc.), and also may communicate with one or more devices allowing a user to interact with the electronic device 1000, and/or may communicate with any device (for example, a router, a modem and so on) allowing the electronic device 1000 to communicate with one or more other computing devices. This communication may be implemented by means of an input/output (I/O) interface 1050. Moreover, the electronic device 1000 also may communicate with one or more networks (for example, a local area network (LAN), a wide area network (WAN) and/or a public network such as the Internet) via a network adapter 1060. As shown in FIG. 10, the network adapter 1060 communicates with other modules of the electronic device 1000 through the bus 1030. It should be understood that although not shown in the figures, other hardware and/or software modules may be used in combination with the electronic device 1000, including but not limited to: microcode, device drivers, redundancy processing units, external disk drive arrays, redundant arrays of independent disks (RAID) systems, tape drives and data backup and storage systems, etc.

With description of the above embodiments, it will be readily understood by those skilled in the art that the exemplary embodiments described herein may be implemented by software or may be implemented by means of software in combination with the necessary hardware. Thus, the technical solutions according to the embodiments of the present disclosure may be embodied in the form of a software product which may be stored in a nonvolatile storage medium (which may be CD-ROM, USB flash disk, mobile hard disk and the like) or on network, including a number of instructions for enabling a computing device (which may be a personal computer, a server, a terminal device, or a network device and the like) to perform the method according to the embodiments of the present disclosure.

In an exemplary embodiment of the present disclosure, there is further provided a computer-readable storage medium storing a program product capable of implementing the above method in this specification. FIG. 11 illustrates a computer program product according to an embodiment of the present disclosure. As shown in FIG. 11, in some embodiments, aspects of the present disclosure may be implemented as a form of a program product, which includes a program code. When the program product runs on a terminal device, the program code is configured to enable the terminal device to perform the steps described in the above “exemplary method” portions of this specification according to the exemplary embodiments of the present disclosure.

The program product configured to implement the above method is described according to the embodiments of the present disclosure. The program product may adopt a portable compact disc read-only memory (CD-ROM) and include a program code, and may run on a terminal device such as a personal computer. However, the program product of the present disclosure is not limited thereto. In this document, a readable storage medium may be any tangible medium that can contain or store a program for use by or in connection with an instruction execution system, apparatus, or device.

Any combination of one or more readable medium(s) may be utilized by the program product. The readable medium may be a readable signal medium or a readable storage medium. The readable storage medium may be, for example, but not limited to, an electronic, magnetic, optical, electromagnetic, infrared, or semiconductor system, apparatus, or device, or any suitable combination of the foregoing. More concrete examples (a non-exhaustive list) of the readable storage medium include the following: an electrical connection having one or more wires, a portable diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing.

A computer readable signal medium may include a propagated data signal with readable program code embodied therein, for example, in baseband or as part of a carrier wave. Such a propagated data signal may take any of a variety of forms, including, but not limited to, electro-magnetic, optical, or any suitable combination thereof. The readable signal medium may be any readable medium that is not a readable storage medium and that can communicate, propagate, or transport a program for use by or in connection with an instruction execution system, apparatus, or device.

Program code embodied on a readable medium may be transmitted using any appropriate medium, including but not limited to wireless, wireline, optical fiber cable, RF, etc., or any suitable combination of the foregoing.

Program code for carrying out operations of the present disclosure may be written in any combination of one or more programming languages, including an object-oriented programming language such as Java, C++ or the like and conventional procedural programming languages, such as the “C” programming language or similar programming languages. The program code may execute entirely on the user's computing device, partly on the user's computing device, as a stand-alone software package, partly on the user's computing device and partly on a remote computing device or entirely on the remote computing device or server. In a scenario involved with a remote computing device, the remote computing device may be coupled to the user's computing device through any type of network, including a local area network (LAN) or a wide area network (WAN), or may be coupled to an external computing device (for example, through the Internet using an Internet Service Provider).

It is to be noticed that although a plurality of modules or units of a device for action execution have been mentioned in the above detailed description, this partition is not compulsory. Actually, according to the embodiments of the present disclosure, features and functions of two or more modules or units as described above may be embodied in one module or unit. Conversely, features and functions of one module or unit as described above may be further embodied in more modules or units.

In addition, steps of the method in the present disclosure are described in a particular order in the accompanying drawings. However, this does not require or imply to execute these steps necessarily according to the particular order, or this does not mean that the expected result cannot be implemented unless all the shown steps are executed. Additionally, some steps may be omitted, a plurality of steps may be combined into one step for execution, and/or one step may be decomposed into a plurality of steps for execution.

With description of the above embodiments, it will be readily understood by those skilled in the art that the exemplary embodiments described herein may be implemented by software or may be implemented by means of software in combination with the necessary hardware. Thus, the technical solutions according to the embodiments of the present disclosure may be embodied in the form of a software product which may be stored in a nonvolatile storage medium (which may be CD-ROM, USB flash disk, mobile hard disk and the like) or on network, including a number of instructions for enabling a computing device (which may be a personal computer, a server, a terminal device, or a network device and the like) to perform the method according to the embodiments of the present disclosure.

Other embodiments of the present disclosure will be apparent to those skilled in the art from consideration of the specification and practice of the present disclosure disclosed here. The present disclosure is intended to cover any variations, uses, or adaptations of the present disclosure following the general principles thereof and including such departures from the present disclosure as come within known or customary practice in the art. It is intended that the specification and embodiments be considered as exemplary only, with a true scope and spirit of the present disclosure being indicated by the appended claims.

What is claimed is:

1. A dummy metal filling method, comprising:
providing an initial layout, wherein the initial layout comprises a potential line;
determining same-layer and same-net metal wires of each metal pattern layer based on a wiring connection relationship in the initial layout, wherein the same-layer and same-net metal wires are wirings positioned on a same metal pattern layer and connected to a same potential line;
determining a to-be-filled region in the each metal pattern layer based on the same-layer and same-net metal wires;
filling same-layer metal wires into the to-be-filled region in the each metal pattern layer, and adding a connection hole, such that the same-layer metal wires are connected to the same potential line; and
adding dummy metal on a layout where the filling the same-layer metal wires is completed, to output a target layout.

2. The dummy metal filling method according to claim 1, wherein the determining the same-layer and same-net metal wires of the each metal pattern layer based on the wiring connection relationship in the initial layout comprises:
determining, based on the wiring connection relationship in the initial layout, same-net metal wires connected to the same potential line; and
screening the same-net metal wires at a same metal pattern layer, to obtain the same-layer and same-net metal wires.

3. The dummy metal filling method according to claim 1, wherein before the filling the same-layer metal wires into the to-be-filled region in the each metal pattern layer, and adding the connection hole, such that the same-layer metal wires are connected to the same potential line, the method further comprises:
determining filling information of the same-layer metal wires in each to-be-filled region based on the to-be-filled region and a preset filling parameter of the same-layer metal wires, to fill the to-be-filled region in the each metal pattern layer by using the filling information of the same-layer metal wires.

4. The dummy metal filling method according to claim 3, wherein the filling parameter of the same-layer metal wires comprises at least one of a width of the same-layer metal wire, an interval between the same-layer metal wire and the same-layer and same-net metal wire, and an interval between adjacent same-layer metal wires.

5. The dummy metal filling method according to claim 3, wherein the filling information of the same-layer metal wires in the each to-be-filled region comprises at least one of filling number, filling positions, and actual filling intervals of the same-layer metal wires.

6. The dummy metal filling method according to claim 1, wherein the filling the same-layer metal wires into the to-be-filled region in the each metal pattern layer comprises:
filling the same-layer metal wires into the to-be-filled region in the each metal pattern layer in a repeated filling manner and/or a staggered filling manner, wherein the same-layer metal wires using the repeated filling manner are connected to the same potential line, and the same-layer metal wires using the staggered filling manner are alternately connected to different potential lines.

7. The dummy metal filling method according to claim 1, wherein the potential line comprises at least one of a power wire and a ground wire with different voltage values.

8. The dummy metal filling method according to claim 1, wherein the adding the dummy metal on the layout where the filling the same-layer metal wires is completed, to output the target layout comprises:
adding the dummy metal on the layout where the filling the same-layer metal wires is completed; and
verifying, based on a preset design rule, the layout where the filling the dummy metal is completed, to obtain a verification result; and
when the verification result indicates successful verification, outputting the target layout succeeding in verification.

9. The dummy metal filling method according to claim 1, wherein the determining the to-be-filled region in the each metal pattern layer based on the same-layer and same-net metal wires comprises:
when an interval between two adjacent same-layer and same-net metal wires meets a preset condition, determining a region between the two adjacent same-layer and same-net metal wires as the to-be-filled region.

10. The dummy metal filling method according to claim 9, wherein the preset condition comprises the interval between the two adjacent same-layer and same-net metal wires being greater than or equal to a preset interval threshold.

11. A dummy metal filling apparatus, comprising:
an initial layout providing module configured to provide an initial layout, wherein the initial layout comprises a potential line;
a same-layer and same-net determination module configured to determine same-layer and same-net metal wires of each metal pattern layer based on a wiring connection relationship in the initial layout, wherein the same-layer and same-net metal wires are wirings positioned on a same metal pattern layer and connected to a same potential line;
a filling region determination module configured to determine a to-be-filled region in the each metal pattern layer based on the same-layer and same-net metal wires of each metal pattern layer;
a same-layer metal filling module configured to fill same-layer metal wires into the to-be-filled region in the each metal pattern layer, and add a connection hole, such that the same-layer metal wires are connected to the same potential line; and
a target layout output module configured to add dummy metal on a layout where the filling the same-layer metal wires is completed, to output a target layout.

12. An electronic device, comprising:
a processor; and
a memory configured to store executable instructions of the processor;
wherein the processor is configured to perform the dummy metal filling method according to claim 1 by executing the executable instructions.

13. A computer-readable storage medium storing a computer program thereon, wherein the computer program is executable by the processor, whereby the dummy metal filling method according to claim 1 is implemented.
